(19) United States
(12) Patent Application Publication
(10) Pub. No.: US 2023/0108919 A1
(43) Pub. Date: Apr. 6, 2023

(54) METHOD FOR PREDICTING FRACTURE HEIGHT DURING FRACTURING STIMULATION IN MULTI-LAYER FORMATION

(71) Applicant: Southwest Petroleum University, Chengdu City (CN)

(72) Inventors: Pingli Liu, Chengdu City (CN); Xiang Chen, Chengdu City (CN); Jian Yang, Chengdu City (CN); Juan Du, Chengdu City (CN); Weihua Chen, Chengdu City (CN); Fei Liu, Chengdu City (CN); Guan Wang, Chengdu City (CN); Jinming Liu, Chengdu City (CN); Zhifeng Luo, Chengdu City (CN); Fengcheng Lou, Chengdu City (CN); Qiang Wang, Chengdu City (CN); Chunhong Lv, Chengdu City (CN)

(21) Appl. No.: 17/952,993

(22) Filed: Sep. 26, 2022

(30) Foreign Application Priority Data
Sep. 26, 2021 (CN) 2021111305535

(51) Int. Cl. E21B 49/00; E21B 43/26

(52) U.S. Cl. CPC E21B 49/006; E21B 43/26; E21B 2200/20

(57) ABSTRACT

The present invention discloses a method for predicting fracture height during fracturing stimulation in multi-layer formation, comprising specific steps of: (1) acquiring basic parameters; (2) calculating a displacement discontinuity quantity of an artificial fracture; (3) calculating induced stress generated by the fracture; (4) calculating stress intensity factors at a fracture tip without considering a fracture tip plasticity; (5) calculating sizes of a plastic zone; (6) calculating stress intensity factors at the fracture tip considering the plastic zone; and (7) judging a relationship between the stress intensity factors and a fracture toughness. The present invention is suitable for multiple stratums, and the influences of parameters of tip plasticity, induced stress, crustal stress, and rock mechanics are considered so that a calculation result is more accurate and calculation efficiency is higher.

### TECHNICAL FIELD

The present invention relates to a fracturing stimulated technology during development of oil or gas fields, particularly to a method for predicting fracture height during fracturing stimulation in multi-layer formation. It belongs to the field of reservoir stimulation.

### BACKGROUND ART

Hydraulic fracturing and acid fracturing are important technical means to increase oil or gas reservoir production. A fracture height is an important parameter to describe a geometric dimension of fracture, so an accurate prediction of the fracture height can effectively avoid some risks. With the continuous exploration and development of petroleum, existing petroleum reservoirs are mostly thin layers, and there is an interlayer between petroleum reservoirs. Thus, multi-layer fracturing is a development trend in the future. In addition, with the continuous improvement of drilling technology, there are more and more oil and gas wells with large spans and long intervals, and multi-stage fracturing is becoming popular. However, an artificial fracture formed in the first fracturing has a significant impact on the fracture propagation in the next fracturing. In addition, due to a stress concentration effect, a plastic zone appears at fracture tips. This results in that the linear elastic fracture theory is no longer applicable to the prediction of fracture height propagation. Therefore, it is necessary to develop a method for predicting fracture height during fracturing treatment, which takes into account factors such as multi-layer formation, multiple fractures, tip plasticity, formation stress, and rock mechanics.

### SUMMARY OF THE INVENTION

The present invention aims to provide a method for predicting fracture height during fracturing stimulation in multi-layer formation in view of the above shortcomings, and specific technical solutions are as follows.

In step S1, parameters of geology, rock mechanics, and artificial fracture are acquired, which specifically comprise formation stress, shear modulus, Poisson's ratio, fracture toughness, and position and height of artificial fracture.

In step S2, displacement discontinuity quantities of n artificial fractures are calculated. A displacement discontinuity method (DDM) may be used to divide each fracture into m displacement discontinuity units, and a displacement discontinuity quantity of each unit of each fracture may be calculated by the following formula (Jizhou Tang, Kan Wu, Yanchao Li, et al. Numerical investigation of the interactions between hydraulic fracture and bedding planes with non-orthogonal approach angle[J]. Engineering Fracture Mechanics, 2018, 200:1-16.):

$$\{ \begin{matrix}{σ}_{SL}^{i} = {\sum }_{k = 1}^{mn} ( {A}_{SL , SL}^{ik} {D}_{SL}^{k} + {A}_{SL , SH}^{ik} {D}_{SH}^{k} + {A}_{SL , NN}^{ik} {D}_{NN}^{k} ) \\ {σ}_{SH}^{i} = {\sum }_{k = 1}^{mn} ( {A}_{SH , SL}^{ik} {D}_{SL}^{k} + {A}_{SH , SH}^{ik} {D}_{SH}^{k} + {A}_{SH , NN}^{ik} {D}_{NN}^{k} ) \\ {σ}_{NN}^{i} = {\sum }_{k = 1}^{mn} ( {A}_{NN , SL}^{ik} {D}_{SL}^{k} + {A}_{NN , SH}^{ik} {D}_{SH}^{k} + {A}_{NN , NN}^{ik} {D}_{NN}^{k} )\end{matrix} , \\ ( i = 1 , 2 , … , mn ) \qquad ( 1 )$$

wherein:

where D is a displacement discontinuity quantity (m); A is a stress influence coefficient (Pa/m); σ is stress (Pa); SL, SH, and NN are subscripts, and represent length direction, height direction, and width direction of fracture, respectively; i and k are superscripts, and indicate the i^{th} unit and the k^{th} unit, respectively; γ(γ=Bᵢ−βⱼ) is an inclination angle difference between the i^{th} unit and the k^{th} unit (rad); φ(φ=θᵢ−θⱼ) is a deflection angle difference between the i^{th} unit and the k^{th} unit (rad); G is a shear modulus (Pa); and v is a Poisson's ratio.

In step S3, the induced stress generated by the n artificial fractures on an n+1^{th} fracture is calculated. Similarly, when the n+1^{th} fracture is divided into m displacement discontinuity units, the induced stress generated by the n artificial fractures on a j^{th} unit of the n+1^{th} fracture may be calculated by the following formula:

$${Δσ}_{NN}^{j} = {\sum }_{k = 1}^{mn} ( {B}_{NN , SL}^{jk} {D}_{SL}^{k} + {B}_{NN , SH}^{jk} {D}_{SH}^{k} + {B}_{NN , NN}^{jk} {D}_{NN}^{k} ) , ( j = 1 , 2 , … , m ) \qquad ( 3 )$$

wherein:

$$\{ \begin{matrix}\begin{matrix}{B}_{NN , SL}^{jk} = {sin}^{2} β {C}_{r} ( 2 {J}_{8} - {x}_{3} {J}_{10} ) + {cos}^{2} β {sin}^{2} θ {C}_{r} ( 2 {vJ}_{8} - {x}_{3} {J}_{13} ) \\ - {cos}^{2} β {cos}^{2} θ {C}_{r} {x}_{3} {J}_{16} - sin 2 β sin θ {C}_{r} [ ( 1 - v ) {J}_{9} - {x}_{3} {J}_{11} ] \\ + sin 2 β cos θ {C}_{r} ( {J}_{6} + {vJ}_{5} - {x}_{3} {J}_{12} ) - {cos}^{2} β sin 2 θ {C}_{r} ( - {vJ}_{7} - {x}_{3} {J}_{19} )\end{matrix} \\ \begin{matrix}{B}_{NN , SH}^{jk} = {sin}^{2} β {C}_{r} ( 2 {vJ}_{9} - {x}_{3} {J}_{11} ) + {cos}^{2} β {sin}^{2} θ {C}_{r} ( 2 {J}_{9} - {x}_{3} {J}_{14} ) \\ - {cos}^{2} β {cos}^{2} θ {C}_{r} {x}_{3} {J}_{17} - sin 2 β sin θ {C}_{r} [ ( 1 - v ) {J}_{8} - {x}_{3} {J}_{13} ] \\ + sin 2 β cos θ {C}_{r} ( - {vJ}_{7} - {x}_{3} {J}_{19} ) - {cos}^{2} β sin 2 θ {C}_{r} ( {J}_{6} + {vJ}_{4} - {x}_{3} {J}_{15} )\end{matrix} \\ \begin{matrix}{B}_{NN , NN}^{jk} = {sin}^{2} β {C}_{r} [ {J}_{6} + ( 1 - 2 v ) {J}_{5} - {x}_{3} {J}_{12} ] + {cos}^{2} β {sin}^{2} θ {C}_{r} [ {J}_{6} + ( 1 - 2 v ) {J}_{4} - {x}_{3} {J}_{15} ] \\ + {cos}^{2} β {cos}^{2} θ {C}_{r} ( {J}_{6} - {x}_{3} {J}_{18} ) - sin 2 β sin θ {C}_{r} [ ( 2 v - 1 ) {J}_{7} - {x}_{3} {J}_{19} ] \\ - sin 2 β cos θ {C}_{r} {x}_{3} {J}_{16} + {cos}^{2} β sin 2 θ {C}_{r} {x}_{3} {J}_{17}\end{matrix}\end{matrix} \qquad ( 4 )$$

wherein: Δσ is the induced stress (Pa); and B is the stress influence coefficient (Pa/m).

In step S4, stress intensity factors at a fracture tip of the n+1^{th} fracture without considering a fracture tip plasticity based on an equilibrium height theory are calculated. The stress intensity factors K_{I+} and K_{I-} at an upper tip and a lower tip of the fracture may be respectively calculated according to the following formula (Liu Songxia, Valkó Peter P. A Rigorous Hydraulic-Fracture Equilibrium-Height Model for Multilayer Formations[J]. SPE Production & Operations, 2018, 33 (02):214-234.):

$$\{ \begin{matrix}{K}_{I -} = {\sum }_{r = 1}^{δ} [ {K}_{I -} ( m , {a}_{r} , - {y}_{d , r} ) - {K}_{I -} ( m , {a}_{r} , - {y}_{u , r} ) ] \\ {K}_{I +} = {\sum }_{r = 1}^{δ} [ {K}_{I +} ( - m , {a}_{r} , {y}_{u , r} ) - {K}_{I +} ( - m , {a}_{r} , {y}_{d , r} ) ]\end{matrix} , y ∈ [ - c , c ] \qquad ( 5 )$$

wherein:

$$\{ \begin{matrix}m = ρ g ; {a}_{r} = {p}_{ref} + ρ g ( {d}_{mid} - {d}_{ref} ) - ( {σ}_{h}^{r} + {Δσ}_{NN}^{r} ) \\ {K}_{I} ( m , {a}_{r} , y ) = \frac{\begin{matrix}2 c \sqrt{c + y} ( 2 {a}_{r} + mc ) {sin}^{- 1} ( \sqrt{\frac{c - y}{2 c}} ) - ( c + y ) \sqrt{c - y} [ 2 {a}_{r} + m ( 2 c - y ) ]\end{matrix}}{2 \sqrt{π c ( c + y )}}\end{matrix} \qquad ( 6 )$$

where δ is a number of formations; ρ is a fluid density (kg/m³); g is an acceleration of gravity (m/s²); p_{ref} is a pressure at a depth of a middle portion of a perforation (Pa); d_{mid} is a depth of a middle portion of the fracture (m); d_{ref} is the depth of the middle portion of the perforation (m); ρ^{r}ₕ is a minimum horizontal principal stress of an r^{th} stratum (Pa); and c is a half height of the fracture (m).

In step S5, sizes of a plastic zone at the fracture tip of the n+1^{th} fracture are calculated. The sizes Sᵤ and Sₗ of the plastic zone at the upper tip and the lower tip may be respectively calculated according to the following formula (Yuwei Li, Min Long, Jizhou Tang, et al. A hydraulic fracture height mathematical model considering the influence of plastic region at fracture tip[J]. Petroleum Exploration and Development, 2020, 47(01):175-185):

$$\{ \begin{matrix}{S}_{u} = {\frac{π}{2} [ \frac{{K}_{I +}}{{σ}_{h}^{r}} ]}^{2} \\ {S}_{l} = {\frac{π}{2} [ \frac{{K}_{I -}}{{σ}_{h}^{r}} ]}^{2}\end{matrix} \qquad ( 7 )$$

In step S6, stress intensity factors at the fracture tip of the n+1^{th} fracture considering the plastic zone are calculated. The stress intensity factors K′_{I+} and K′_{I-} at the upper tip and the lower tip of the fracture are respectively calculated according to the following formula:

$$\{ \begin{matrix}{K}_{I -}^{′} = \sqrt{\frac{1}{π \frac{2 c + {S}_{u} + {S}_{l}}{2}}} {\int }_{- \frac{2 c + {S}_{u} + {S}_{l}}{2}}^{\frac{2 c + {S}_{u} + {S}_{l}}{2}} [ - ρ {gy}_{r} + {p}_{ref} + ρ g ( {d}_{mid} - {d}_{ref} ) - ( {σ}_{h}^{r} + {Δσ}_{NN}^{r} ) ] \sqrt{\frac{\frac{2 c + {S}_{u} + {S}_{l}}{2} - y}{\frac{2 c + {S}_{u} + {S}_{l}}{2} + y}} dy \\ {K}_{I +}^{′} = \sqrt{\frac{1}{π \frac{2 c + {S}_{u} + {S}_{l}}{2}}} {\int }_{- \frac{2 c + {S}_{u} + {S}_{l}}{2}}^{\frac{2 c + {S}_{u} + {S}_{l}}{2}} [ - ρ {gy}_{r} + {p}_{ref} + ρ g ( {d}_{mid} - {d}_{ref} ) - ( {σ}_{h}^{r} + {Δσ}_{NN}^{r} ) ] \sqrt{\frac{\frac{2 c + {S}_{u} + {S}_{l}}{2} + y}{\frac{2 c + {S}_{u} + {S}_{l}}{2} - y}} dy\end{matrix} \qquad ( 8 )$$

where yᵣ is a depth (m).

In step S7, whether the stress intensity factors K′_{I+} and K′_{I-} are greater than a fracture toughness at the fracture tip is judged. When the stress intensity factors K′_{I+} and K′_{I-} are greater than the fracture toughness, the operation gets back to the step S4. When the stress intensity factors K′_{I+} and K′_{I-} are not greater than the fracture toughness, the operation is ended to output the n+1^{th} fracture height.

In the calculation method above, the same symbols involved in all formulas have the same meanings when being used in preceding and following descriptions, and all symbols are common after being marked once.

A calculation flow of the fracture height disclosed in the present invention is shown in FIG. 1.

The inventor found that the existing patent CN108280275B disclosed a method for predicting a fracture high of hydraulic fracturing in dense sandstone reservoir only applicable to 3 stratums (interlayer or caprock—reservoir—interlayer or underlayer), in which commercial software ABAQUS was used, a basic principle was a finite element method, and influences of induced stress and plastic zone were not considered. The patent CN110348032A disclosed a numerical simulation method for a stratification development shale stratum hydraulic fracture height, and the patent CN112257304A disclosed a method for predicting a shale stratum vertical well hydraulic fracture height, in which an extended finite element method was used, and influences of multiple stratums, plastic zone, and induced stress were also not considered. The main differences between this series of patents and the method of the present invention are as follows: (1) basic ideas and principles are different, and calculation methods are different; (2) final purposes are similar, but realization ways are different, wherein the present invention has a higher calculation efficiency; and (3) in the present invention, an applicable number of stratums is not limited, more comprehensive factors are considered, and a calculation result is more accurate.

The present invention has the advantages that: the present invention is applicable to multiple stratums; a stress concentration effect at a tip, which changes rock from elasticity to plasticity, is considered; an influence of adjacent artificial fractures on a new fracture propagation is considered; the influences of parameters of formation stress and rock mechanics are considered. Thus, a fracture height is predicted more accurately. The displacement discontinuity method and the equilibrium height theory are used so that the calculation speed is higher.

Other advantages, objects, and features of the present invention will be partially reflected by the following description and understood by those skilled in the art through researching and practicing the present invention.

### BRIEF DESCRIPTION OF THE DRAWINGS

FIG. 1 is a flow chart of predicting fracture height during fracturing stimulation in multi-layer formation.

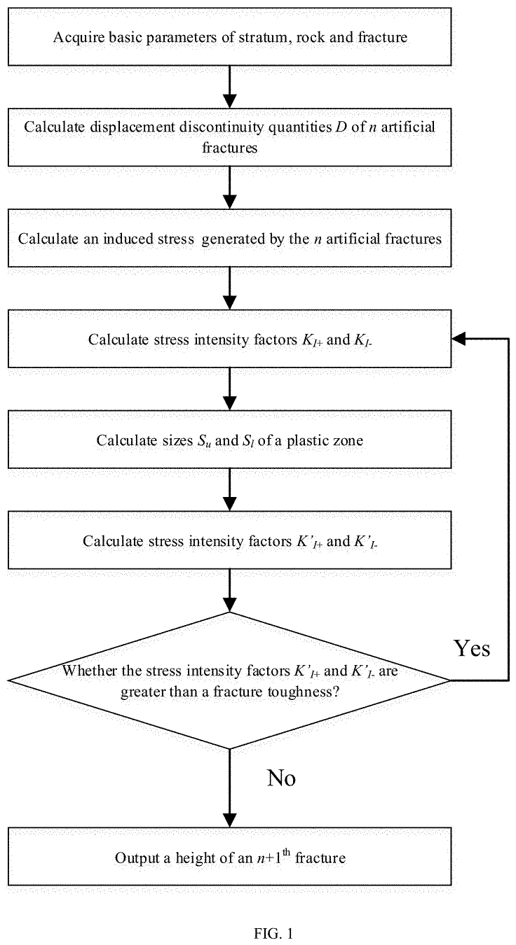

FIG. 2 is a cross-section view of fracture height during fracturing stimulation in multi-layer formation.

### DETAILED DESCRIPTION OF THE PREFERRED EMBODIMENTS

The preferred embodiments of the present invention are described hereinafter with reference to the drawings. It should be understood that the preferred embodiments described herein are only used for describing and explaining the present invention and are not intended to limit the present invention.

After fracturing a dense sandstone gas reservoir, basic parameters are measured as shown in Table 1.

TABLE 1
Basic parameter table

| | | | Minimum | | | |
|---|---|---|---|---|---|---|
| | | | horizontal | Fracture | Shear | |
| Layer | Top depth | Thickness | principal | toughness | modulus | Poisson's |
| number | (m) | (m) | stress (MPa) | (MPa · m^{1/2}) | (GPa) | ratio |
| #1 | 2680 | 100 | 44 | 5 | 50 | 0.35 |
| #2 | 2780 | 20 | 38 | 2 | 20 | 0.17 |
| #3 | 2800 | 40 | 44 | 5 | 30 | 0.25 |
| #4 | 2840 | 20 | 38 | 2 | 20 | 0.17 |
| #5 | 2860 | 40 | 44 | 5 | 30 | 0.25 |
| #6 | 2900 | 20 | 48 | 7 | 40 | 0.3 |
| #7 | 2920 | 100 | 53 | 9 | 50 | 0.35 |

| | | |
|---|---|---|
| Perforation | Depth of middle portion of perforation (m) | 2850 |
| Fluid | Density (kg/m³) | 1100 |

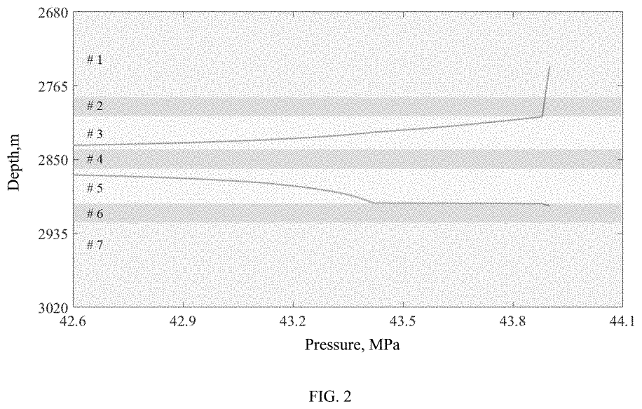

Allowing that n=1, a distance between an n^{th} fracture and an n+1^{th} fracture is 25 m, a height of the n^{th} fracture is 25 m, a pressure at the depth of the middle portion of the perforation is 42.6 MPa, and a step size of the pressure is set to be 0.01 MPa. Based on the data in Table 1, steps S1 to S7 are executed in sequence, and a formula is a numerical solution. The final calculation results are shown in FIG. 2.

The above is only the preferred embodiments of the present invention and does not limit the present invention in any form. Although the present invention has been disclosed by the preferred embodiments, the preferred embodiments are not intended to limit the present invention. Those skilled in the art can make some changes or modifications as equivalent embodiments with equivalent changes by using the technical contents disclosed above without departing from the scope of the technical solutions of the present invention. However, for the contents not departing from the scope of the technical solutions of the present invention, any simple modifications, equivalent changes, and modifications made to the above embodiments according to the technical essence of the present invention are still included in the scope of the technical solutions of the present invention.

1. A method for predicting fracture height during fracturing stimulation in multi-layer formation, comprising the following steps:
S1: acquiring parameters of geology, rock mechanics, and artificial fracture;
S2: calculating displacement discontinuity quantities D of n artificial fractures based on a displacement discontinuity method;
S3: calculating induced stress Δσ generated by then artificial fractures on an n+1^{th} fracture;
S4: calculating stress intensity factors K_{I+} and K_{I-} at fracture tips of the n+1^{th} fracture without considering the fracture tip plasticity based on an equilibrium height theory;
S5: calculating sizes Sᵤ and Sₗ of a plastic zone at the fracture tip of the n+1^{th} fracture;
S6: calculating stress intensity factors K′_{I+} and K′_{I-} at fracture tips of the n+1^{th} fracture considering the plastic zone;
S7: judging whether the stress intensity factors K′_{I+} and K′_{I-} are greater than a fracture toughness at the fracture tip; when the stress intensity factors K′_{I+} and K′_{I-} are greater than the fracture toughness, getting back to the step S4; and when the stress intensity factors K′_{I+} and K′_{I-} are not greater than the fracture toughness, ending the operation to output the n+1^{th} fracture height.

2. The method for predicting fracture height during fracturing stimulation in multi-layer formation according to claim 1, wherein in the step S6, the stress intensity factors K′_{I+} and K′_{I-} at an upper tip and a lower tip of the n+1^{th} fracture are that:
$$\{ \begin{matrix}{K}_{I -}^{′} = \sqrt{\frac{1}{π \frac{2 c + {S}_{u} + {S}_{l}}{2}}} {\int }_{- \frac{2 c + {S}_{u} + {S}_{l}}{2}}^{\frac{2 c + {S}_{u} + {S}_{l}}{2}} [ - ρ {gy}_{r} + {p}_{ref} + ρ g ( {d}_{mid} - {d}_{ref} ) - ( {σ}_{h}^{r} + {Δσ}_{NN}^{r} ) ] \sqrt{\frac{\frac{2 c + {S}_{u} + {S}_{l}}{2} - y}{\frac{2 c + {S}_{u} + {S}_{l}}{2} + y}} dy \\ {K}_{I +}^{′} = \sqrt{\frac{1}{π \frac{2 c + {S}_{u} + {S}_{l}}{2}}} {\int }_{- \frac{2 c + {S}_{u} + {S}_{l}}{2}}^{\frac{2 c + {S}_{u} + {S}_{l}}{2}} [ - ρ {gy}_{r} + {p}_{ref} + ρ g ( {d}_{mid} - {d}_{ref} ) - ( {σ}_{h}^{r} + {Δσ}_{NN}^{r} ) ] \sqrt{\frac{\frac{2 c + {S}_{u} + {S}_{l}}{2} + y}{\frac{2 c + {S}_{u} + {S}_{l}}{2} - y}} dy\end{matrix}$$
where ρ is a fluid density (kg/m³); g is an acceleration of gravity (m/s²); p_{ref} is a pressure at a depth of a middle portion of a perforation (Pa); d_{mid} is a depth of a middle portion of the fracture (m); d_{ref} is the depth of the middle portion of the perforation (m); ρ^{r}ₕ is a minimum horizontal principal stress of an r^{th} stratum (Pa); c is a half height of the fracture (m); and yᵣ is a depth (m).
